(19) United States
(12) Patent Application Publication
(10) Pub. No.: US 2022/0336673 A1
(43) Pub. Date: Oct. 20, 2022

(54) OXIDE ELECTRODE FOR DEVICE WITH POLARIZABLE MATERIAL LAYER

(71) Applicant: Korea Advanced Institute of Science and Technology, Daejeon (KR)

(72) Inventors: Sanghun JEON, Daejeon (KR); Youngin GOH, Daejeon (KR)

(21) Appl. No.: 17/720,200

(22) Filed: Apr. 13, 2022

(30) Foreign Application Priority Data
Apr. 15, 2021 (KR) 10-2021-0048980

(51) Int. Cl. H01L 29/78; H01L 29/49

(52) U.S. Cl. CPC H01L 29/78391; H01L 29/4966

(57) ABSTRACT

Disclosed is an oxide electrode for a device including a top electrode, a bottom electrode, and a polarizable material layer interposed between the top electrode and the bottom electrode. An oxide electrode is used as the bottom electrode unlike the top electrode.

### CROSS-REFERENCE TO RELATED APPLICATIONS

This application claims priority under 35 U.S.C. § 119 to Korean Patent Application No. 10-2021-0048980 filed on Apr. 15, 2021, in the Korean Intellectual Property Office, the disclosure of which is incorporated by reference herein in its entirety.

### BACKGROUND

Embodiments of the present disclosure described herein relate to an oxide electrode for a device with a polarizable material layer.

With the advent of a hyper-connected society thanks to the introduction of IoT technology, it is expected that the amount of information demand will increase, and thus, it is expected that enormous energy is consumed for transmission, calculation, and application of data.

To satisfy the amount of information demand thus rapidly increasing, there is a need for new ultra-power-saving nanoelectronic devices and architectural technologies to be applied to a system capable of operating at ultra-power-saving while they have higher performance than a conventional semiconductor device.

Accordingly, a polarizable material having non-volatile properties capable of being applied to various device technology-based architectures have recently been attracting attention. The polarizable material has spontaneous polarization that is clearly identified in two directions, and has a feature that the direction of spontaneous polarization is reversed by an external electric field. Accordingly, the polarizable material is used in a non-volatile memory and an ultra-low-power switching device because the polarizable material has fast switching speed and excellent scalability with a CMOS semiconductor device.

However, because an oxide vacancy is generated at a contact interface, the polarizable material has deteriorated ferroelectric properties, an unstable polarization switching state, and short lifespan.

Accordingly, embodiments described below are intended to propose a technology for solving problems of the conventional polarizable material.

### SUMMARY

Embodiments of the present disclosure provide a technology for forming a bottom electrode in contact with a polarizable material layer as an oxide electrode capable of suppressing an oxide vacancy at a boundary by supplying oxygen to the polarizable material layer for the purpose of improving a ferroelectric property, stabilizing a polarization switching state, and extending a lifespan.

Moreover, embodiments of the present disclosure provide a technology for forming a top electrode in contact with the polarizable material layer as an oxide electrode.

However, the technical problems to be solved by the present disclosure are not limited to the above problems, and may be variously expanded without departing from the technical spirit and scope of the present disclosure.

According to an embodiment, a device includes a top electrode, a bottom electrode, and a polarizable material layer interposed between the top electrode and the bottom electrode. An oxide electrode is used as the bottom electrode unlike the top electrode.

According to an aspect, the oxide electrode suppresses an oxide vacancy at a boundary between the oxide electrode and the polarizable material layer by supplying oxygen to the polarizable material layer.

According to another aspect, the oxide electrode is formed of metal oxide including RuO₂.

According to still another aspect, the oxide electrode is formed on a barrier layer formed of one of metal nitride and metal oxide.

According to yet another aspect, the metal nitride includes at least one of TiAlN, TiN, TaN, ZrN, and HfN.

According to yet another aspect, the metal oxide includes at least one of HfO₂, ZrO₂, and Al₂O₃.

According to yet another aspect, a nitride electrode is used as the top electrode.

According to yet another aspect, a device including the polarizable material layer is used as a two-terminal device based on a fact that there is a work-function difference between the bottom electrode and the top electrode.

According to an embodiment, a method for manufacturing a device including a polarizable material layer includes preparing a barrier layer formed of one of metal nitride and metal oxide, forming an oxide electrode used as a bottom electrode on the barrier layer, forming the polarizable material layer on the oxide electrode, and forming a nitride electrode used as a top electrode on the polarizable material layer.

According to an aspect, the forming of the oxide electrode includes forming the oxide electrode for suppressing an oxide vacancy at a boundary between the oxide electrode and the polarizable material layer by supplying oxygen to the polarizable material layer.

According to another aspect, the forming of the nitride electrode includes forming the nitride electrode unlike the bottom electrode such that the device including the polarizable material layer is used as a two-terminal device based on a fact that there is a work-function difference between the bottom electrode and the top electrode.

According to an embodiment, a device includes a top electrode, a bottom electrode, and a polarizable material layer interposed between the top electrode and the bottom electrode. An oxide electrode is used as each of the top electrode and the bottom electrode.

According to an aspect, the oxide electrode used as each of the top electrode and the bottom electrode suppresses an oxide vacancy at boundaries between the polarizable material layer and the oxide electrode, which is used as each of the top electrode and the bottom electrode, by supplying oxygen to the polarizable material layer.

According to another aspect, the oxide electrode is formed of metal oxide including RuO₂.

According to still another aspect, the oxide electrode used as each of the top electrode and the bottom electrode is formed on a bottom barrier layer or a top barrier layer, which is formed of one of metal nitride and metal oxide.

According to yet another aspect, the metal nitride includes at least one of TiAlN, TiN, TaN, ZrN, and HfN.

According to yet another aspect, the metal oxide includes at least one of HfO₂, ZrO₂, and Al₂O₃.

According to yet another aspect, the device including the polarizable material layer is used as a three-terminal device based on a fact that there is no work-function difference between the bottom electrode and the top electrode.

According to an embodiment, a method for manufacturing a device including a polarizable material layer includes preparing a bottom barrier layer formed of one of metal nitride and metal oxide, forming an oxide electrode used as a bottom electrode on the bottom barrier layer, forming a polarizable material layer on the oxide electrode, and disposing the oxide electrode used as a top electrode on the polarizable material layer and a top barrier layer formed of one of metal nitride and metal oxide in contact with the top electrode.

According to an aspect, the forming of the oxide electrode includes forming the oxide electrode for suppressing an oxide vacancy at a boundary between the polarizable material layer and the oxide electrode used as the bottom electrode by supplying oxygen to the polarizable material layer.

According to another aspect, the disposing of the oxide electrode and the top barrier layer includes forming the oxide electrode for suppressing an oxide vacancy at a boundary between the polarizable material layer and the oxide electrode used as the top electrode by supplying oxygen to the polarizable material layer.

According to yet another aspect, the disposing of the oxide electrode and the top barrier layer includes forming the oxide electrode in the same method as the bottom electrode such that the device including the polarizable material layer is used as a three-terminal device based on a fact that there is no work-function difference between the bottom electrode and the top electrode.

### BRIEF DESCRIPTION OF THE FIGURES

The above and other objects and features of the present disclosure will become apparent by describing in detail embodiments thereof with reference to the accompanying drawings.

FIG. 1 is a cross-sectional view for describing a device having a polarizable material layer, according to an embodiment.

FIG. 2 is a view for describing ferroelectric properties according to materials forming a barrier layer in a device having a polarizable material layer, according to an embodiment.

FIG. 3 is a cross-sectional view illustrating a two-terminal device used by a device having the polarizable material layer shown in FIG. 1.

FIG. 4 is a flowchart illustrating a method of manufacturing a device having a polarizable material layer shown in FIG. 1.

FIG. 5 is a cross-sectional view illustrating a device having a polarizable material layer, according to another embodiment.

FIGS. 6 and 7 are cross-sectional views illustrating a three-terminal device used by a device having the polarizable material layer shown in FIG. 5.

FIG. 8 is a flowchart illustrating a method of manufacturing a device having a polarizable material layer shown in FIG. 5.

FIG. 9 is a view for describing the superiority of a device having a polarizable material layer, according to embodiments.

### DETAILED DESCRIPTION

Hereinafter, a description will be given in detail for embodiments of the present disclosure with reference to the following drawings. However, the present disclosure are not limited or restricted by the embodiments. Further, the same reference signs/numerals in the drawings denote the same members.

Furthermore, the terminologies used herein are used to properly express the embodiments of the present disclosure, and may be changed according to the intentions of a viewer or the manager or the custom in the field to which the present disclosure pertains. Therefore, definition of the terminologies should be made according to the overall disclosure set forth herein. For example, in the specification, the singular forms include plural forms unless particularly mentioned. Furthermore, the terms “comprises” and/or “comprising” used herein does not exclude presence or addition of one or more other components, steps, operations, and/or elements in addition to the aforementioned components, steps, operations, and/or elements.

Moreover, it should be understood that various embodiments of the present disclosure are not necessarily mutually exclusive although being different from each other. For example, specific shapes, structures, and characteristics described herein may be implemented in other embodiments without departing from the spirit and scope of the present disclosure in relation to one embodiment. Besides, it should be understood that the location, arrangement, or configuration of individual components in each of presented categories of an embodiment may be changed without departing from the spirit and scope of the present disclosure.

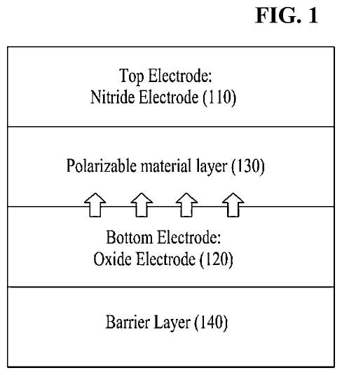

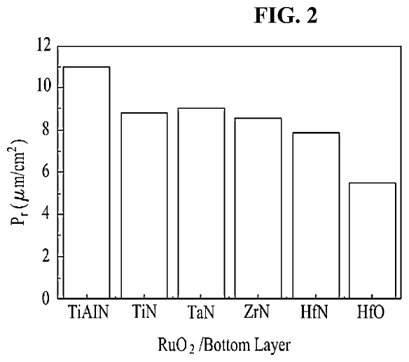

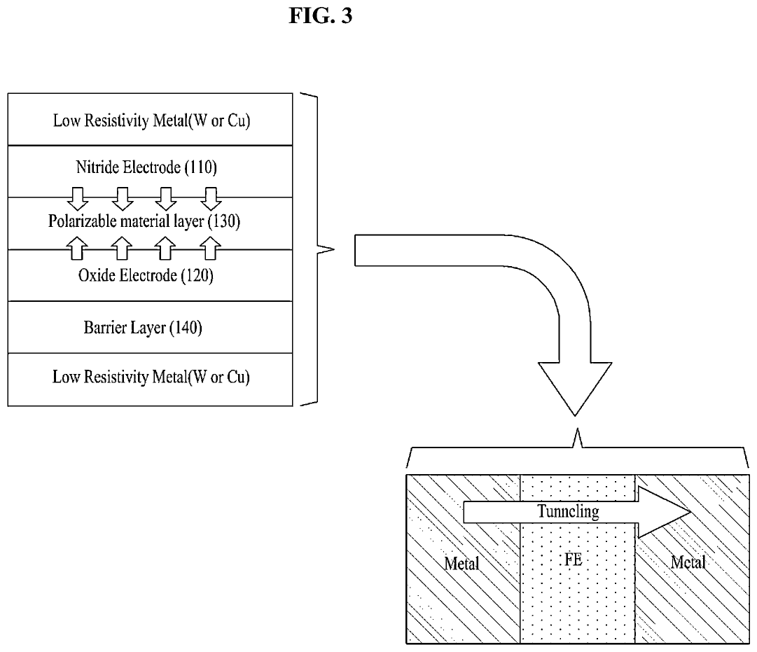

FIG. 1 is a cross-sectional view for describing a device having a polarizable material layer, according to an embodiment. FIG. 2 is a view for describing ferroelectric properties according to materials forming a barrier layer in a device having a polarizable material layer, according to an embodiment. FIG. 3 is a cross-sectional view illustrating a two-terminal device used by a device having the polarizable material layer shown in FIG. 1.

Referring to FIG. 1, a device 100 having a polarizable material layer according to an embodiment may include a top electrode 110, a bottom electrode 120, and a polarizable material layer 130 interposed between the top electrode 110 and the bottom electrode 120.

Because the polarizable material layer 130 has ferroelectric or antiferroelectric properties, the polarizable material layer 130 has a polarization state, which is capable of being arbitrarily set, from among at least two or more polarization states. The polarizable material layer 130 may be formed of an HfO₂ or ZrO-based material, a compound thereof, or a material doped with other elements (e.g., it may be HfₓZr₁₋ₓO₂(HZO) that is HfO₂ where Zr is doped). The polarizable material layer 130 has a property that contributes to the conversion of an oxide vacancy from an orthorhombic phase (o-phase) to a tetragonal phase (t-phase) at a contact interface generated by an oxygen process during a formation process. However, because the excessive oxide vacancy at the contact interface weakens the ferroelectric properties by forming a non-ferroelectric layer, there is a need to suppress an unintentional oxide vacancy at the contact interface.

Accordingly, in the device 100 having a polarizable material layer according to an embodiment, an oxide electrode is used as the bottom electrode 120 in contact with a lower portion of the polarizable material layer 130 unlike the top electrode 110. Hereinafter, the oxide electrode is used as the bottom electrode 120. This means that the bottom electrode 120 is implemented as an oxide electrode. Furthermore, hereinafter, it is described that the oxide electrode is formed of RuO₂, but is not limited thereto. For example, the oxide electrode may be formed of various metal oxides including RuO₂.

The oxide electrode used as the bottom electrode 120 may supply oxygen to the polarizable material layer 130 and may suppress an oxide vacancy at a boundary between an oxide electrode (the bottom electrode 120) and the polarizable material layer 130. As the oxide vacancy at the boundary between the oxide electrode (the bottom electrode 120) and the polarizable material layer 130 is suppressed, void defects at the polarizable material layer 130 are lowered, thereby reducing a non-ferroelectric layer and improving the ferroelectric properties. Accordingly, the stability of the polarization switching state may be improved. Furthermore, as compared to a nitride electrode thus commonly used, the oxide electrode used as the bottom electrode 120 has a high work-function (the oxide electrode has a work-function of 5.1 eV, and the nitride electrode has a work-function of 4.2 eV), low sheet resistance, and high chemical stability, thereby improving the reliability and performance of the device 100 with a polarizable material layer.

As such, because the oxide electrode used as the bottom electrode 120 is not formed on SiO₂ that is a general silicon substrate, the oxide electrode is formed on a barrier layer 140 formed of one of metal nitride and metal oxide having low surface energy. The metal nitride may include at least one of TiAlN, TiN, TaN, ZrN, and HfN, and the metal oxide may include at least one of HfO₂, ZrO₂, and Al₂O₃.

In particular, it is suitable to use the metal nitride as the barrier layer 140 that is a seed layer on which an oxide electrode is formed. The reason is that the oxide electrode diffuses oxygen into the metal oxide, but does not diffuse oxygen into the metal nitride. That is, the barrier layer 140 may be formed of metal nitride such that the oxide electrode used as the bottom electrode 120 does not supply oxygen to the barrier layer 140, but supplies oxygen to only the polarizable material layer 130. For example, as shown in FIG. 2, when the barrier layer 140 is formed of TiAN among metal nitrides, it may be seen that the ferroelectric property of the device 100 with a polarizable material layer is the largest. When the barrier layer 140 is formed of HfO, which is a metal oxide, it may be seen that the ferroelectric property of the device 100 with the polarizable material layer is the smallest.

Unlike the above-described bottom electrode 120, a nitride electrode (e.g., TiN) may be used as the top electrode 110. Hereinafter, a nitride electrode is used as the top electrode 110. This means that the bottom electrode 120 is implemented as an oxide electrode.

As such, as an oxide electrode is used as the bottom electrode 120, and a nitride electrode is used as the top electrode 110, there is a difference in a work-function between the bottom electrode 120 and the top electrode 110. Accordingly, the device 100 with a polarizable material layer in which an oxide electrode is used as the bottom electrode 120 and a nitride electrode is used as the top electrode 110 may be used as a two-terminal device such as a ferroelectric tunnel junction (FTJ) based on the fact that a work-function difference between the bottom electrode 120 and the top electrode 110 is present, as shown in FIG. 3.

Hereinafter, a method of manufacturing the device 100 with a polarizable material layer in which an oxide electrode is used as the bottom electrode 120 and a nitride electrode is used as the top electrode 110 will be described.

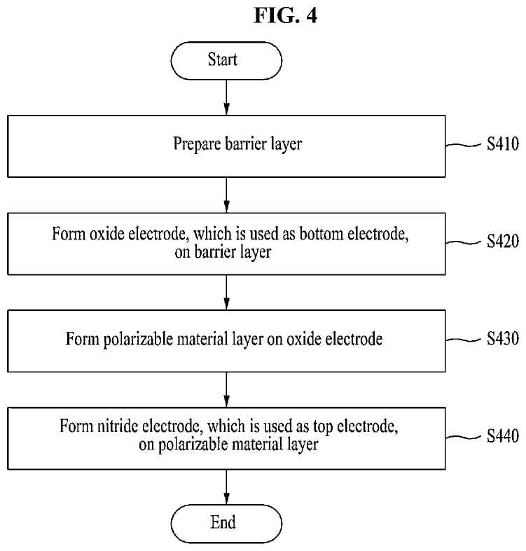

FIG. 4 is a flowchart illustrating a method of manufacturing a device having a polarizable material layer shown in FIG. 1. Hereinafter, it is assumed that a manufacturing method described with reference to FIG. 4 is performed by an automated and mechanized manufacturing system. What is manufactured as the performed result may be the device 100 having a polarizable material layer described with reference to FIG. 1.

Referring to FIG. 4, in operation S410, the manufacturing system may prepare a barrier layer formed of one of metal nitride and metal oxide. For example, the manufacturing system may form the barrier layer formed of metal nitride on low-resistivity metal shown in FIG. 3.

Next, in operation S420, the manufacturing system may form an oxide electrode, which is used as a bottom electrode, on the barrier layer. In more detail, the manufacturing system may form the bottom electrode as the oxide electrode, which suppresses an oxide vacancy at a boundary between the oxide electrode and the polarizable material layer by supplying oxygen to the polarizable material layer. For example, the manufacturing system may deposit RuO₂ that is an oxide electrode having a thickness of 10 nm, on the barrier layer through a thermal evaporation process (a thermal ALD process). In more detail, under a temperature condition of 225° C., the manufacturing system may form the oxide electrode through a thermal evaporation process using a Ru precursor and an O₂ reactant.

Next, in operation S430, the manufacturing system may form a polarizable material layer on the oxide electrode. For example, under the temperature condition of 300° C., the manufacturing system may form a polarizable material layer of 10 nm on the oxide electrode through the thermal evaporation process using Hf and Zr precursors and O₃ reactants.

Afterwards, in operation S440, the manufacturing system may form a nitride electrode, which is used as the top electrode, on the polarizable material layer. For example, the manufacturing system may form the nitride electrode by depositing TiN by 10 nm on the polarizable material layer.

In operation S440, the manufacturing system may form the top electrode as the nitride electrode unlike the bottom electrode such that a device with the polarizable material layer is capable of being used as a two-terminal device based on the fact that a work-function difference between the bottom electrode and the top electrode is present.

Although not shown as a separate operation, after performing operation S410 to operation S440, the manufacturing system may perform heat treatment so as to be crystallized in o-phase.

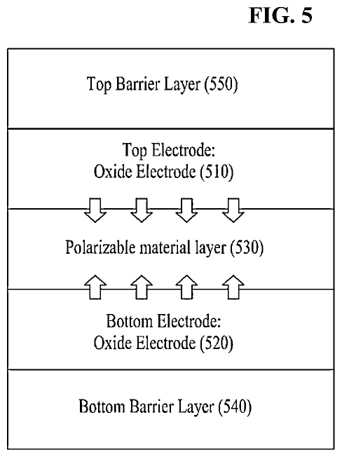

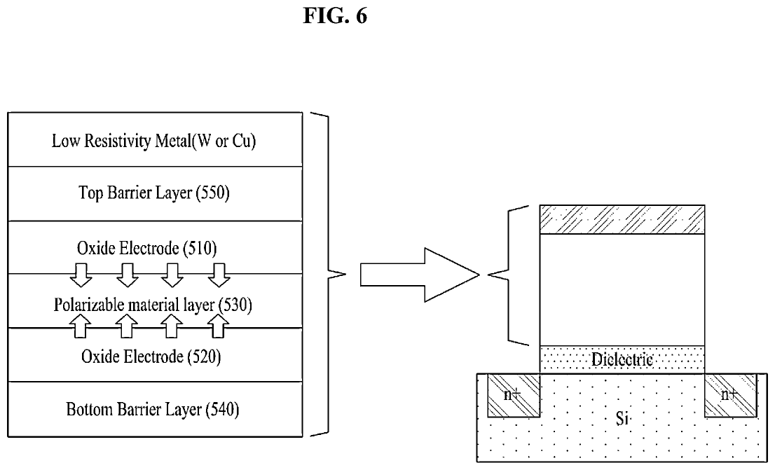

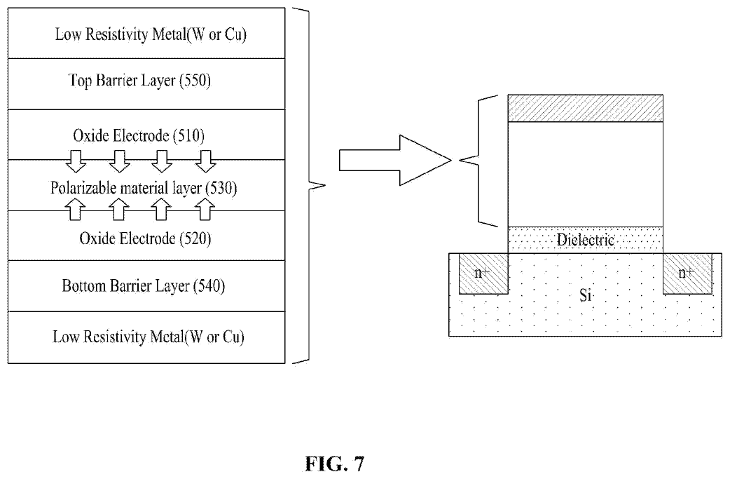

FIG. 5 is a cross-sectional view illustrating a device having a polarizable material layer, according to another embodiment. FIGS. 6 and 7 are cross-sectional views illustrating a three-terminal device used by a device having the polarizable material layer shown in FIG. 5.

Referring to FIG. 5, a device 500 having a polarizable material layer according to another embodiment may include a top electrode 510, a bottom electrode 520, and a polarizable material layer 530 interposed between the top electrode 510 and the bottom electrode 520.

Because the polarizable material layer 530 has ferroelectric or antiferroelectric properties, the polarizable material layer 130 has a polarization state, which is capable of being arbitrarily set, from among at least two or more polarization states. The polarizable material layer 130 may be formed of an HfO₂ or ZrO-based material, a compound thereof, or a material doped with other elements (e.g., it may be HfₓZr₁₋ₓO₂(HZO) that is HfO₂ where Zr is doped). The polarizable material layer 130 has a property that contributes to the conversion of an oxide vacancy from an orthorhombic phase (o-phase) to a tetragonal phase (t-phase) at a contact interface generated by an oxygen process during a formation process. However, because the excessive oxide vacancy at the contact interface weakens the ferroelectric properties by forming a non-ferroelectric layer, there is a need to suppress an unintentional oxide vacancy at the contact interface.

Accordingly, in the device 500 with a polarizable material layer according to another embodiment, an oxide electrode is used as each of the top electrode 510 in contact with an upper portion of the polarizable material layer 530 and the bottom electrode 520 in contact with a lower portion of the polarizable material layer 530. Hereinafter, the oxide electrode is used as each of the top electrode 510 and the bottom electrode 520. This means that the bottom electrode 520 is implemented as an oxide electrode, and the top electrode 510 is also implemented as an oxide electrode. Furthermore, hereinafter, it is described that the oxide electrode is formed of RuO₂, but is not limited thereto. For example, the oxide electrode may be formed of various metal oxides including RuO₂.

The oxide electrode used as each of the top electrode 510 and the bottom electrode 520 may suppress an oxide vacancy at boundaries (a boundary between the bottom electrode 520 and the polarizable material layer 530 and a boundary between the top electrode 510 and the polarizable material layer 530) between the oxide electrode and the polarizable material layer 530 by supplying oxygen to the polarizable material layer 530. As the oxide vacancy at boundaries (a boundary between the bottom electrode 520 and the polarizable material layer 530 and a boundary between the top electrode 510 and the polarizable material layer 530) between the oxide electrode and the polarizable material layer 530 is suppressed, void defects at the polarizable material layer 530 are lowered, thereby reducing a non-ferroelectric layer and improving the ferroelectric properties. Accordingly, the stability of the polarization switching state may be improved. Furthermore, as compared to a nitride electrode thus commonly used, the oxide electrode used as each of the top electrode 510 and the bottom electrode 520 has a high work-function (the oxide electrode has a work-function of 5.1 eV, and the nitride electrode has a work-function of 4.2 eV), low sheet resistance, and high chemical stability, thereby improving the reliability and performance of the device 500 with a polarizable material layer.

As such, because the oxide electrode used as each of the top electrode 510 and the bottom electrode 520 is not formed on SiO₂ that is a general silicon substrate, the oxide electrode is formed on a bottom barrier layer 540 or a top barrier layer 550, which is formed of one of metal nitride and metal oxide having low surface energy. The metal nitride may include at least one of TiAlN, TiN, TaN, ZrN, and HfN, and the metal oxide may include at least one of HfO₂, ZrO₂, and Al₂O₃.

In particular, it is suitable to use the metal nitride as the bottom barrier layer 540 and the top barrier layer 550 that are seed layers on which an oxide electrode is formed. The reason is that the oxide electrode diffuses oxygen into the metal oxide, but does not diffuse oxygen into the metal nitride. That is, the bottom barrier layer 540 and the top barrier layer 550 may be formed of metal nitride such that the oxide electrode used as each of the top electrode 510 and the bottom electrode 520 does not supply oxygen to the bottom barrier layer 540 and the top barrier layer 550, but supplies oxygen to only the polarizable material layer 530.

As such, as the oxide electrode is used as each of the top electrode 510 and the bottom electrode 520, there is no work-function difference between the bottom electrode 520 and the top electrode 510. Accordingly, as shown in FIGS. 6 and 7, the device 500 with a polarizable material layer in which an oxide electrode is used as each of the top electrode 510 and the bottom electrode 520 may be used as a three-terminal device such as a ferroelectric FET (FeFET) based on the fact that the work-function difference between the bottom electrode 520 and the top electrode 510 is not present.

Hereinafter, a method of manufacturing the device 500 with a polarizable material layer in which an oxide electrode is used as each of the top electrode 510 and the bottom electrode 520 will be described.

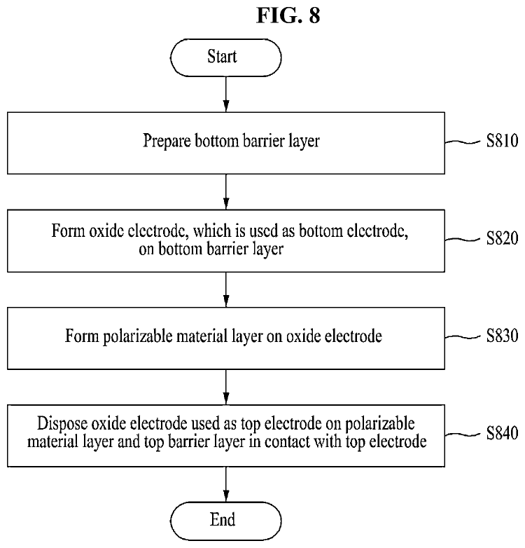

FIG. 8 is a flowchart illustrating a method of manufacturing a device having a polarizable material layer shown in FIG. 5. Hereinafter, it is assumed that a manufacturing method described with reference to FIG. 8 is performed by an automated and mechanized manufacturing system. What is manufactured as the performed result may be the device 500 having a polarizable material layer described with reference to FIG. 5.

Referring to FIG. 8, in operation S810, the manufacturing system may prepare a bottom barrier layer formed of one of metal nitride and metal oxide. For example, the manufacturing system may form the bottom barrier layer formed of metal nitride on low-resistivity metal shown in FIG. 7.

Next, in operation S820, the manufacturing system may form an oxide electrode, which is used as a bottom electrode, on the bottom barrier layer. In more detail, the manufacturing system may form the bottom electrode as the oxide electrode, which suppresses an oxide vacancy at a boundary between the oxide electrode and the polarizable material layer by supplying oxygen to the polarizable material layer. For example, the manufacturing system may deposit RuO₂ that is an oxide electrode having a thickness of 10 nm, on the bottom barrier layer through a thermal evaporation process (a thermal ALD process). In more detail, under a temperature condition of 225° C., the manufacturing system may form the oxide electrode used as a bottom electrode through a thermal evaporation process using a Ru precursor and an O₂ reactant.

Next, in operation S830, the manufacturing system may form a polarizable material layer on the oxide electrode. For example, under the temperature condition of 300° C., the manufacturing system may form a polarizable material layer of 10 nm on the oxide electrode through the thermal evaporation process using Hf and Zr precursors and O₃ reactants.

Afterwards, in operation S840, the manufacturing system may dispose an oxide electrode used as a top electrode on the polarizable material layer and a top barrier layer formed of one of metal nitride and metal oxide in contact with the top electrode. In more detail, the manufacturing system may form the top electrode as the oxide electrode, which suppresses an oxide vacancy at a boundary between the oxide electrode and the polarizable material layer by supplying oxygen to the polarizable material layer. For example, under a temperature condition of 225° C., the manufacturing system may form the oxide electrode used as the top electrode on the polarizable material layer through a thermal evaporation process using a Ru precursor and an O₂ reactant.

In operation S840, the manufacturing system may form the top electrode as the oxide electrode in the same method as the bottom electrode such that a device with the polarizable material layer is capable of being used as a three-terminal device based on the fact that a work-function difference between the bottom electrode and the top electrode is not present.

Although not shown as a separate operation, after performing operation S810 to operation S840, the manufacturing system may perform heat treatment so as to be crystallized in o-phase.

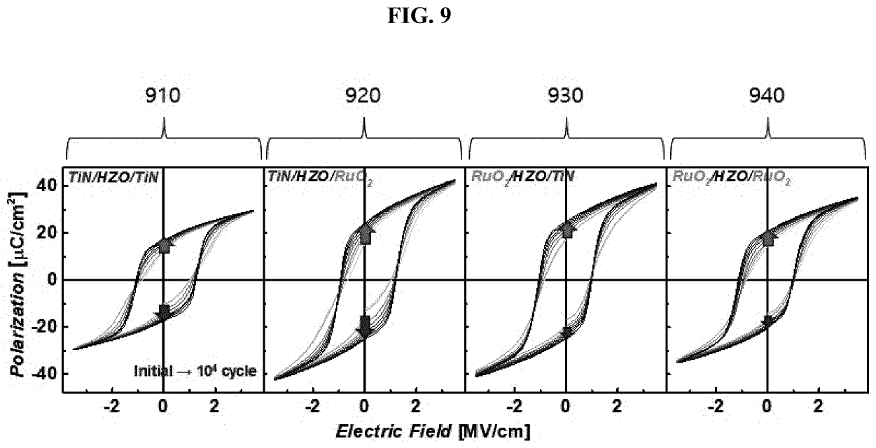

FIG. 9 is a view for describing the superiority of a device having a polarizable material layer, according to embodiments.

Referring to FIG. 9, it may be seen that a ferroelectric property of a device with a conventional polarizable material layer is the worst in a case (910) where a nitride electrode is used as each of a top electrode and a bottom electrode. It may be seen that a ferroelectric property of the device with the polarizable material layer is the best in a case (920) where an oxide electrode is used as only the bottom electrode. In addition, it may be seen that a ferroelectric property of a ferroelectric device in a case (930) where an oxide electrode is used as only the top electrode and a ferroelectric property of a device with a polarizable material layer in a case (940) where an oxide electrode is used as each of the top electrode and the bottom electrode are superior to a ferroelectric property of a device with a conventional polarizable material layer in a case (910) where a nitride electrode is used.

As understood from the above description, as compared to the conventional device in which a nitride electrode is used as the bottom electrode, the device 100 having a polarizable material layer in a case where an oxide electrode is used as the bottom electrode and the device 500 having a polarizable material layer in a case where oxide electrodes are used as a top electrode and a bottom electrode may improve ferroelectric properties, may stabilize a polarization switching state, and may extend a lifespan.

While a few embodiments have been shown and described with reference to the accompanying drawings, it will be apparent to those skilled in the art that various modifications and variations can be made from the foregoing descriptions. For example, adequate effects may be achieved even if the foregoing processes and methods are carried out in different order than described above, and/or the aforementioned elements, such as systems, structures, devices, or circuits, are combined or coupled in different forms and modes than as described above or be substituted or switched with other components or equivalents.

Therefore, other implements, other embodiments, and equivalents to claims are within the scope of the following claims.

According to embodiments, it is possible to improve ferroelectric properties, to stabilize a polarization switching state, and to extend a lifespan by proposing a technology for forming a bottom electrode in contact with a polarizable material layer as an oxide electrode that is capable of suppressing an oxide vacancy at a boundary by supplying oxygen to the polarizable material layer.

Moreover, embodiments provide a technology for forming a top electrode in contact with the polarizable material layer as an oxide electrode.

However, the effects of the present disclosure are not limited to the effects, and may be variously expanded without departing from the spirit and scope of the present disclosure.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A device comprising:
a top electrode;
a bottom electrode; and
a polarizable material layer interposed between the top electrode and the bottom electrode,
wherein an oxide electrode is used as the bottom electrode unlike the top electrode.

2. The device of claim 1, wherein the oxide electrode suppresses an oxide vacancy at a boundary between the oxide electrode and the polarizable material layer by supplying oxygen to the polarizable material layer.

3. The device of claim 2, wherein the oxide electrode is formed of metal oxide including RuO₂.

4. The device of claim 1, wherein the oxide electrode is formed on a barrier layer formed of one of metal nitride and metal oxide.

5. The device of claim 4, wherein the metal nitride includes at least one of TiAlN, TiN, TaN, ZrN, and HfN.

6. The device of claim 4, wherein the metal oxide includes at least one of HfO₂, ZrO₂, and Al₂O₃.

7. The device of claim 1, wherein a nitride electrode is used as the top electrode.

8. The device of claim 7, wherein a device including the polarizable material layer is used as a two-terminal device based on a fact that there is a work-function difference between the bottom electrode and the top electrode.

9. A method for manufacturing a device including a polarizable material layer, the method comprising:
preparing a barrier layer formed of one of metal nitride and metal oxide;
forming an oxide electrode used as a bottom electrode on the barrier layer;
forming the polarizable material layer on the oxide electrode; and
forming a nitride electrode used as a top electrode on the polarizable material layer.

10. The method of claim 9, wherein the forming of the oxide electrode includes:
forming the oxide electrode for suppressing an oxide vacancy at a boundary between the oxide electrode and the polarizable material layer by supplying oxygen to the polarizable material layer.

11. The method of claim 9, wherein the forming of the nitride electrode includes:
forming the nitride electrode unlike the bottom electrode such that the device including the polarizable material layer is used as a two-terminal device based on a fact that there is a work-function difference between the bottom electrode and the top electrode.

12. A device comprising:
a top electrode;
a bottom electrode; and
a polarizable material layer interposed between the top electrode and the bottom electrode,
wherein an oxide electrode is used as each of the top electrode and the bottom electrode.

13. The device of claim 12, wherein the oxide electrode used as each of the top electrode and the bottom electrode suppresses an oxide vacancy at boundaries between the polarizable material layer and the oxide electrode, which is used as each of the top electrode and the bottom electrode, by supplying oxygen to the polarizable material layer.

14. The device of claim 13, wherein the oxide electrode is formed of metal oxide including RuO₂.

15. The device of claim 12, wherein the oxide electrode used as each of the top electrode and the bottom electrode is formed on a bottom barrier layer or a top barrier layer, which is formed of one of metal nitride and metal oxide.

16. The device of claim 15, wherein the metal nitride includes at least one of TiAlN, TiN, TaN, ZrN, and HfN.

17. The device of claim 15, wherein the metal oxide includes at least one of HfO₂, ZrO₂, and Al₂O₃.

18. The device of claim 12, wherein the device including the polarizable material layer is used as a three-terminal device based on a fact that there is no work-function difference between the bottom electrode and the top electrode.

19. A method for manufacturing a device including a polarizable material layer, the method comprising:
preparing a bottom barrier layer formed of one of metal nitride and metal oxide;
forming an oxide electrode used as a bottom electrode on the bottom barrier layer;
forming a polarizable material layer on the oxide electrode; and
disposing the oxide electrode used as a top electrode on the polarizable material layer and a top barrier layer formed of one of metal nitride and metal oxide in contact with the top electrode.

20. The method of claim 19, wherein the forming of the oxide electrode includes:
forming the oxide electrode for suppressing an oxide vacancy at a boundary between the polarizable material layer and the oxide electrode used as the bottom electrode by supplying oxygen to the polarizable material layer.

21. The method of claim 19, wherein the disposing of the oxide electrode and the top barrier layer includes:
forming the oxide electrode for suppressing an oxide vacancy at a boundary between the polarizable material layer and the oxide electrode used as the top electrode by supplying oxygen to the polarizable material layer.

22. The method of claim 19, wherein the disposing of the oxide electrode and the top barrier layer includes:
forming the oxide electrode in the same method as the bottom electrode such that the device including the polarizable material layer is used as a three-terminal device based on a fact that there is no work-function difference between the bottom electrode and the top electrode.
